(19) United States
(12) Patent Application Publication
(10) Pub. No.: US 2026/0165128 A1
(43) Pub. Date: Jun. 11, 2026

(54) ELECTRONIC DEVICES AND METHODS OF MANUFACTURING ELECTRONIC DEVICES

(71) Applicant: Amkor Technology Singapore Holding Pte. Ltd.

(72) Inventors: Mike Kelly, Mesa, AZ (US); Chandra Pendyala, Queen Creek, AZ (US); Young Do Kweon, Chandler, AZ (US)

(73) Assignee: Amkor Technology Singapore Holding Pte. Ltd., (omitted)

(21) Appl. No.: 19/409,285

(22) Filed: Dec. 4, 2025

Related U.S. Application Data
(60) Provisional application No. 63/730,296, filed on Dec. 10, 2024.

(51) Int. Cl. H10W 40/25; H10W 70/05; H10W 70/652; H10W 74/10

(52) U.S. Cl. CPC H10W 40/258; H10W 70/093; H10W 70/652; H10W 74/137

(57) ABSTRACT

In one example, an electronic device includes a redistribution structure, a first electronic component disposed over the redistribution structure, and a second electronic component disposed adjacent the first electronic component and over the redistribution structure. An encapsulant can be disposed around lateral sides of the first electronic component and the second electronic component. A metallic structure is disposed over the encapsulant and the first electronic component, and a first CTE above a beam-neutral axis of the electronic device is balanced with a second CTE below the beam-neutral axis of the electronic device. Other examples and related methods are also disclosed herein.

### PRIORITY

This application claims priority to U.S. Patent Provisional Application No. 63/730,296 filed on Dec. 10, 2024 and entitled “Electronic Devices and Methods of Manufacturing Electronic Devices,” which is incorporated herein by reference.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2H show an example method for manufacturing an electronic device.

FIG. 3A shows a cross-sectional view of an example electronic device.

FIG. 3B shows a top view of the example electronic device of FIG. 3A.

FIG. 4A shows a cross-sectional view of an example electronic device.

FIG. 4B shows a top view of the example electronic device of FIG. 4A.

FIG. 5 shows a cross-sectional view of an example electronic device.

FIG. 6 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of the stated features, but do not preclude the presence or addition of one or more other features.

The terms “first,” “second,” etc. may be used herein to describe various elements. These elements are not limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or to describe two elements indirectly coupled by one or more other elements. For example, if element A is coupled to element B, then element A can be contacting element B or indirectly coupled to element B by an intervening element C. Similarly, the terms “over” or “on” may be used to describe two elements directly contacting each other or describe two elements indirectly coupled by one or more other elements. Unless specified otherwise, the term “coupled” can refer to a mechanical coupling or an electrical coupling.

### DESCRIPTION

An example electronic device can include a redistribution structure comprising a first CTE, a first electronic component disposed over the redistribution structure, and a second electronic component disposed adjacent the first electronic component and over the redistribution structure. A gap can be defined between the first electronic component and the second electronic component. An encapsulant can be disposed in the gap and around the first electronic component and the second electronic component. An outer side of the first electronic component and an outer side of the second electronic component can be substantially coplanar with an outer side of the encapsulant. A metallic structure can be disposed over the outer side of the encapsulant, the outer side of the first electronic component, and the outer side of the second electronic component. The metallic structure comprises a second CTE balanced with the first CTE of the redistribution structure.

Another electronic device includes a redistribution structure, a first electronic component disposed over the redistribution structure, and a second electronic component disposed adjacent the first electronic component and over the redistribution structure. An encapsulant can be disposed around lateral sides of the first electronic component and the second electronic component. A metallic structure is disposed over the encapsulant and the first electronic component, and a first CTE above a beam-neutral axis of the electronic device is balanced with a second CTE below the beam-neutral axis of the electronic device.

An example method of manufacturing an electronic device includes the steps of providing a redistribution structure, providing a first electronic component over the redistribution structure, and providing a second electronic component adjacent the first electronic component and over the redistribution structure. An encapsulant can be provided around lateral sides of the first electronic component and the second electronic component. The encapsulant can be substantially coplanar with the first electronic component and the second electronic component. A metallic structure can be provided over the encapsulant and the first electronic component. A first CTE of the metallic structure is balanced with a second CTE of the redistribution structure.

Other examples are included in the present disclosure. Such examples may be found in the figures, in the claims, or in the description of the present disclosure.

Various example electronic devices and related methods can improve mechanical behavior of electronic devices undergoing thermal changes. In some examples, the Coefficient of Thermal Expansion (CTE) of a redistribution structure can be dominated by the metal included in the conductive layers of the redistribution structure. In electronic devices having redistribution structures, the greater CTE of the redistribution structure, as compared to the CTE of the semiconductor materials of electronic components within the electronic device, can lead to warpage of electronic device. In some devices, the difference in thermal expansion of the redistribution structure as compared to the electronic components can result in a bowed shape or cry shape as an electronic device is heated or cools after heating. A changing shape during heating (or cooling) can result in difficulties joining the electronic device to a substrate.

In some examples, the CTE can be analyzed at various locations of the electronic device, and a metallic structure can be selectively coupled to the electronic device to reduce warpage. CTEs described herein can be given in parts per million change per degree Celsius (ppm/° C.).

In various examples, the metallic structure can be added above a beam-neutral axis of the electronic device. Placing the metal structure at a greater distance from the beam neutral axis can result in greater regulation of the mechanical behavior of the electronic device under heat changes. The selective placement of the metallic structure can result in a CTE on an upper side of an electronic component that matches, approximates, or compensates for the CTE of a redistribution structure or other structure on a lower side of the electronic component. Selective placement of metal can have minimal degradation of thermal performance in some examples.

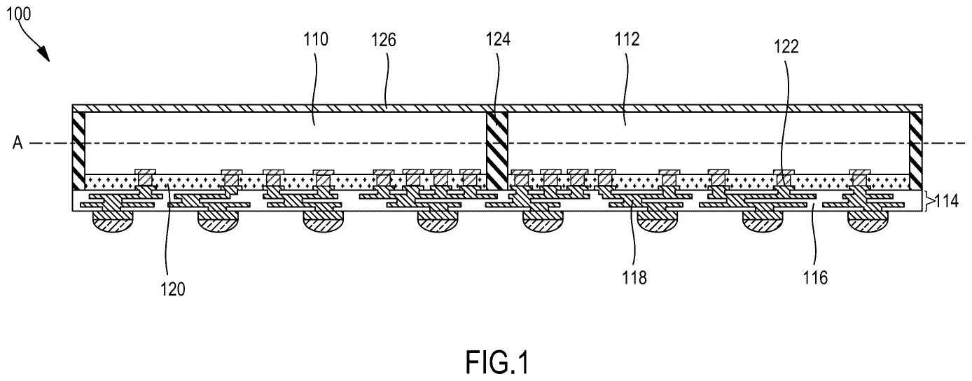

FIG. 1 shows a cross-sectional view of an example electronic device 100. In the example shown in FIG. 1, electronic device 100 comprises electronic component 110 and electronic component 112 coupled to redistribution structure 114. Redistribution structure 114 can comprise dielectric structure 116 and conductive structure 118. Encapsulant 126 can be disposed around electronic components 110 and 112. In some examples, external interconnects 130 can be coupled to redistribution structure 114.

In various examples, metallic structure 128 can be coupled to a side of electronic components 110 and 112 opposite redistribution structure 114. Axis A can define a beam-neutral axis of electronic device 100. Metallic structure 128 can be selectively provided (e.g., plated) to reduce or compensate for a difference in CTEs between portions of electronic device 100 above and below beam-neutral axis A. Metallic structure 128 positioned on a side of electronic device 100 opposite redistribution structure 114 can reduce or compensate for the difference in CTE above beam-neutral axis A and below beam-neutral axis A, which can reduce bowing of electronic device 100.

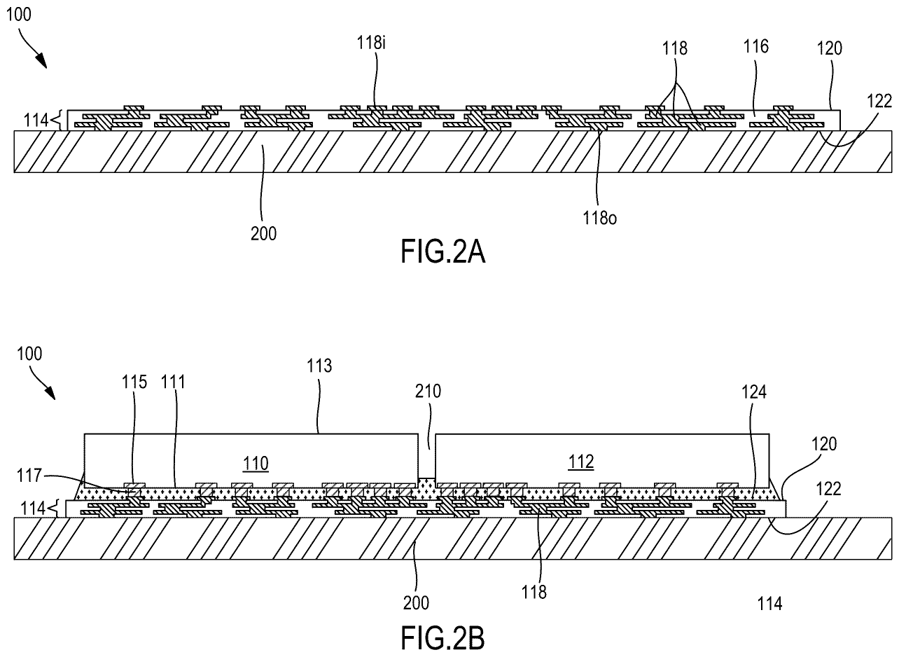

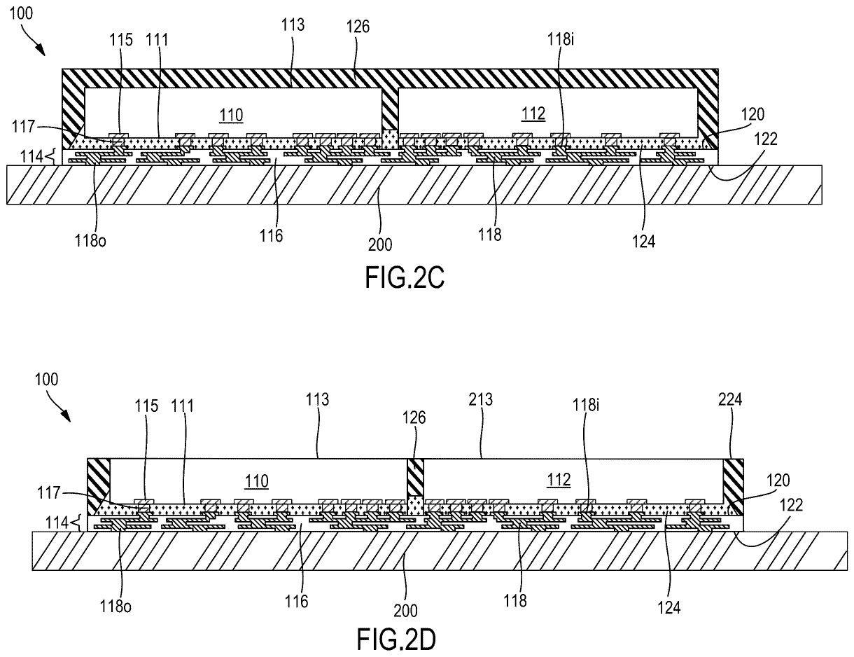

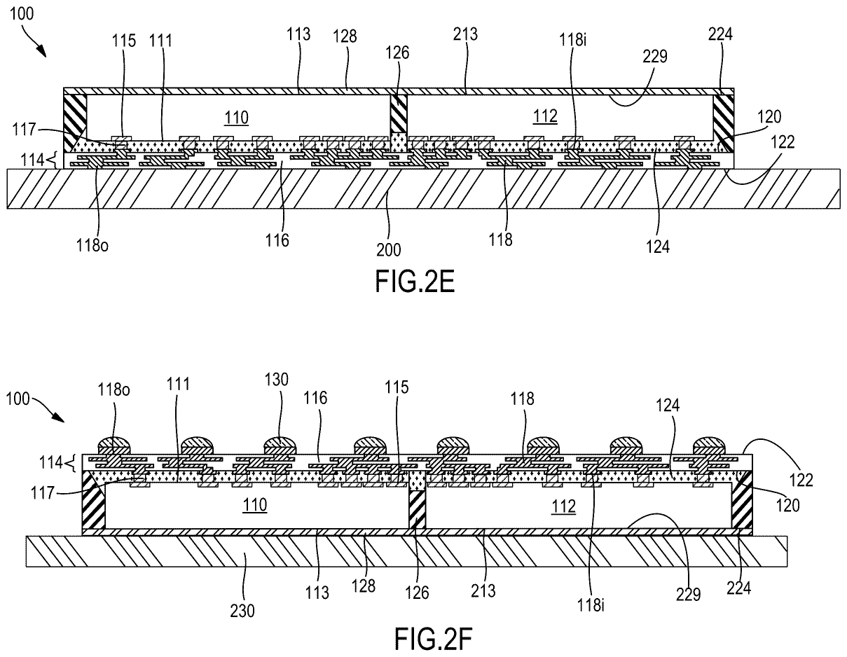

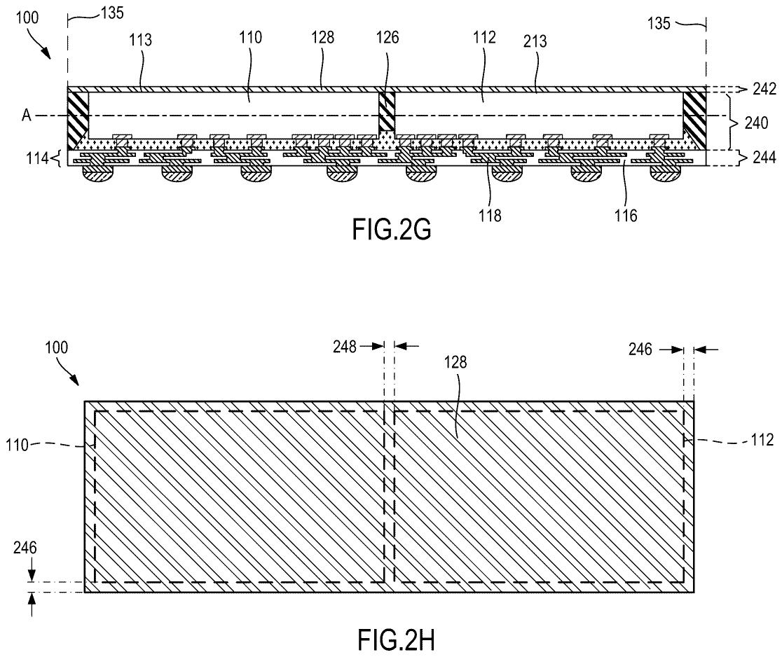

FIGS. 2A to 2H show cross-sectional views of an example method for manufacturing an example electronic device, such as electronic device 100 in FIG. 1. Referring now to FIG. 2A, electronic device 100 is shown at an early stage of manufacture. In the example shown in FIG. 2A, redistribution structure 114 can be provided on carrier 200. Redistribution structure 114 can comprise dielectric structure 116 and conductive structure 118. Conductive structure 118 can comprise inner terminals 118i and outer terminals 118o.

In some examples, redistribution structure 114 can be provided on carrier 200. Carrier 200 can comprise a substantially planar support structure. In some examples, carrier 200 can comprise or be referred to as a plate, a board, a wafer, a panel, or a tape. For example, carrier 200 can be provided as a round wafer or a square or rectangular panel. In some examples, the width of carrier 200 can range from approximately 100 millimeters (mm) to approximately 300 mm. In some examples, the width of carrier 200 can range from approximately 300 millimeters mm to approximately 650 mm. In some examples, the width of carrier 200 can be greater than 650 mm. As used herein with numeric values, the term approximately can mean +/−5%, +/−10%, +/−15%, +/−20%, or +/−25%.

Carrier 200 can support multiple redistribution structures 114 and/or multiple electronic devices 100 during processing. Multiple redistribution structures 114 can be provided in wafer form or in a grid, array, strip(s), rows, columns, or other arrangements on carrier 200.

In some examples, carrier 200 can include a temporary bond layer on the upper side of carrier 200. The temporary bond layer can comprise or be referred to as a temporary bonding film, a temporary bonding tape, or a temporary adhesive coating. For example, the temporary bond layer can comprise a heat release tape (or film), an optical release tape (or film), a chemical release tape (or film), or a laser release tape (or film), wherein the adhesive strength of the temporary bond layer is weakened or removed by heat, light, chemical reaction, or laser energy, respectively. The temporary bond layer can facilitate separation of redistribution structure 114 from carrier 200 at a later stage of manufacture.

In accordance with various examples, redistribution structure 114 comprises dielectric structure 116 and conductive structure 118. In some examples, dielectric structure 116 can comprise or be referred to as one or more dielectric layers. For instance, the one or more dielectric layers can comprise one or more layers of polymer organic dielectric materials (e.g., polyimide (PI), benzocyclobutene (BCB), polybenzoxazole (PBO), etc.), solder mask, etc. One or more layers or elements of conductive structure 118 can be interleaved with elements or layers of dielectric structure 116. Dielectric structure 116 can maintain the shape of redistribution structure 114 and can structurally support conductive structure 118. In some examples, the thickness of a single layer of dielectric structure 116 could range from approximately 2 μm to approximately 40 μm, from approximately 4 μm to approximately 25 μm, or from approximately 5 μm to approximately 12 μm. A complete redistribution structure 114 can comprise any number of layers such as, for example, one to ten layers or two to five layers. In some examples, the overall thickness of redistribution structure 114 can range from approximately 5 μm to 200 μm.

Conductive structure 118 can include one or more conductive layers and form conductive paths horizontally and vertically through dielectric structure 116. Conductive structure 118 can be provided with multiple patterns, and the respective patterns can be electrically connected to outer terminals 118o and inner terminals 118i of conductive structure 118. Conductive structure 118 can comprise or be referred to as one or more conductive layers defining signal distribution elements, traces, vias, pads, conductive patterns, conductive paths, wiring patterns, circuit patterns, or under bump metallization (UBM). In some examples, conductive structure 118 can comprise one or more layers of copper (Cu), aluminum (Al), tin (Sn), titanium (Ti), titanium tungsten (TiW), gold (Au), silver (Ag), nickel (Ni), palladium (Pd), or combinations or alloys thereof. The layers and elements of conductive structure 118 can be provided by electrolytic plating, electroless plating, sputtering, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), or any other suitable metal deposition process. The thickness of conductive structure 118 can range from approximately 2 micrometers (μm) to approximately 50 μm, approximately 2 micrometers (μm) to approximately 20 μm, or from approximately 2 micrometers (μm) to approximately 10 μm. The thickness of conductive structure 118 can refer to individual layers of conductive structure 118. In some examples, a line width/line spacing of conductive structure 118 can range between approximately 2 μm/2 μm and approximately 30 μm/30 μm, approximately 2 μm/2 μm and approximately 20 μm/20 μm, approximately 2 μm/2 μm and approximately 10 μm/10 μm, approximately 2 μm/2 μm and approximately 5 μm/5 μm or approximately 2 μm/2 μm and approximately 3 μm/3 μm. The line width/line spacing of conductive structure 118 refers to the width of individual traces within conductive structure 118 (i.e., line width) and the distance between adjacent traces within conductive structure 118 (i.e., line spacing). Conductive structure 118 can provide electrical signal paths (e.g., vertical paths and horizontal paths) through dielectric structure 116.

Conductive structure 118 can be exposed at an inner side 120 of redistribution structure 114 and can comprise inner terminals 118 along inner side 120 of redistribution structure 114. Conductive structure 118 can also be exposed at an outer side 122 of redistribution structure 114 and can comprise outer terminals 118o along outer side 122 of redistribution structure 114. In some examples, inner terminals 118i and/or outer terminals 118o can comprise or be referred to as pads, lands, studs, or UBM. Layers and elements of conductive structure 118 can electrically couple inner terminals 118i with outer terminals 118o.

It is contemplated and understood that one or more layers or elements of conductive structure 118 can be interleaved with dielectric structure 116 and that dielectric structure 116 and conductive structure 118 can each include any number of layers in redistribution structure 114. Redistribution structure 114 can have a CTE of approximately 17 to approximately 50, approximately 18 to approximately 30, or approximately 18 to approximately 25. In some examples, the CTE of the conductive material (e.g., copper) of redistribution structure 114 is approximately 17, and the CTE of the dielectric material (e.g., polyimide) of redistribution structure 114 can be greater than 30 and can range from approximately 30 to approximately 200 depending on temperature. The semiconductor material (e.g., silicon) of electronic components 110 and 112 (FIG. 1) can have a CTE of approximately 3.

In some examples, redistribution structure 114 can be a redistribution layer (“RDL”) substrate. RDL substrates can comprise one or more conductive redistribution layers and one or more dielectric layers. RDL substrates can be formed layer by layer over an electronic component to which the RDL substrate is coupled. RDL substrates can also be formed layer by layer over a carrier, which can be entirely or partially removed after an electronic component is coupled to the RDL substrate. RDL substrates can be manufactured layer by layer as a wafer-level substrate on a round wafer in a wafer-level process, or as a panel-level substrate on a rectangular or square panel carrier in a panel-level process.

RDL substrates can be formed in an additive buildup process and can include one or more dielectric layers alternatingly formed with one or more conductive layers. RDL substrates can define respective conductive redistribution patterns or traces configured to collectively fan-out electrical traces outside the footprint of the electronic component, or to fan-in electrical traces within the footprint of the electronic component. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask.

The dielectric layers of an RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, PI, BCB, or PBO. Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layers can comprise silicon nitride (Si3N4), silicon oxide (SiO2), or silicon oxynitride (SiON). The inorganic dielectric layers can be formed by growing the inorganic dielectric layers using an oxidation or nitridization process instead of using photo-defined organic dielectric materials. Such inorganic dielectric layers can be filler-free, without strands, weaves, or other dissimilar inorganic particles. In some examples, the RDL substrates can omit a permanent core structure generally associated with pre-formed, laminate substrates, as described below. RDL substrates can be referred to as a build-up substrates.

In some examples, redistribution structure 114 can be a pre-formed substrate. Pre-formed substrates can be manufactured prior to attachment to an electronic component (or prior to disposal over carrier 200) and can comprise dielectric layers between respective conductive layers. The conductive layers can comprise copper and can be formed using an electroplating process. The dielectric layers can be relatively thicker, non-photo-definable layers that can be attached as a pre-formed film or sheet rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising BT or FR4, and dielectric and conductive layers can be formed on the permanent core structure. In other examples, the pre-formed substrate can be a coreless substrate and omit the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process.

FIG. 2B shows electronic device 100 at a later stage of manufacture. In the example of FIG. 2B, one or more electronic component(s) 110 and one or more electronic components 112 can be provided on inner side 120 of redistribution structure 114. Electronic components 110 and 112 can be coupled to conductive structure 118. For example, electronic components 110 and 112 can be coupled to inner terminals 118i of redistribution structure 114. In accordance with various examples, electronic component 110 can comprise a front side 111 facing the inner side 120 of redistribution structure 114 and a backside 113 opposite front side 111. In some examples, front side 111 can comprise or be referred to as an active side of electronic component 110. Electronic component 110 can include contacts 115 on the active side of the electronic component 110. Contacts 115 can comprise or be referred to as contact pads, bond pads, or studs, in some examples. In some examples, contacts 115 can comprise a metal exposed via an inorganic dielectric material such as silicon dioxide (SiO2) or silicon nitride (Si3N4) located over the active side of electronic component 110. For example, contacts 115 can be the final metal layer formed at the back-end-of-line (BEOL) stage. In some examples, contacts 115 can be exposed via an organic dielectric material or a solder resist material formed over the BEOL layers.

In some examples, connectors 117 can couple electronic component 110 to redistribution structure 114. Connectors 117 can couple contacts 115 of electronic component 110 to inner terminals 118i. Connectors 117 can comprise or be referred to as bumps, tin-lead (SnPb) bumps, lead-free bumps, copper pillars, stud bumps, pillars, posts, solder capped metal pillars, etc.

In accordance with various examples, electronic component 110 can comprise or be referred to as a die, chip, semiconductor package (e.g., multiple interconnected and/or stacked die and/or one or more die coupled to an interposer substrate), passive component, antenna patch, or power device. In some examples, electronic component 110 can comprise a digital signal processor (DSP), network processor, power management unit, audio processor, radio-frequency (RF) circuit, wireless baseband processor, system-on-chip (SoC) processor, sensor, or application-specific integrated circuit (ASIC). In some examples, electronic component 110 can be configured to perform calculation and control processing, store data, or remove noise from electrical signals.

In some examples, one or more electronic component(s) 112 can be coupled to conductive structure 118 of redistribution structure 114. In some examples, electronic component(s) 112 can be coupled to inner terminals 118i of conductive structure 118. For example, electronic component 112 can be coupled to conductive structure 118 as described above with respect to electronic component 110. In some examples, electronic component 112 can be similar to or the same as electronic component 110. In some examples, electronic component 112 can comprise or be referred to as a passive device (e.g., capacitor, resistor, integrated passive device (IPD), etc.). In some examples, electronic component 112 can comprise or be referred to as semiconductor die or chip. In some examples, electronic component 112 can comprise a semiconductor package. For example, electronic component 112 can include multiple interconnected and/or stacked die and/or one or more die coupled to an interposer substrate. In some examples, the one or more electronic component(s) 112 can comprise memory die or memory package(s) (e.g., a high bandwidth memory (HBM)) and the one or more electronic component(s) 110 can comprise logic die (e.g., CPU, GPU, etc.) or system on chip (SoC) die.

In accordance with various examples, electronic component 110 can be disposed adjacent electronic component 112. Gap 210 can be defined between the sidewalls of electronic component 110 and electronic component 112. Redistribution structure 114 can extend laterally beyond the sidewalls of electronic component 110. Redistribution structure 114 can extend laterally beyond the sidewalls of electronic component 112.

In some examples, underfill 124 can be provided between electronic component 110 and redistribution structure 114 and between electronic component 112 and redistribution structure 114. Underfill 124 can be between inner side 120 of redistribution structure 114 and front side 111 of electronic component 110. Underfill 124 can contact inner side 120 of redistribution structure 114 and front side 111 of electronic component 110. In some examples, underfill 124 can surround and/or contact connectors 117.

Underfill 124 can comprise an electrically insulating material. In some examples, underfill 124 can be devoid of inorganic fillers. In some examples, underfill 124 can comprise or be referred to as a capillary underfill (CUF), a non-conductive paste (NCP), a non-conductive film (NCF), an anisotropic conductive film (ACF), or an anisotropic conductive paste (ACP). In some examples, underfill 124 can be provided between electronic components 110, 112 and redistribution structure 114 and then cured. Underfill 124 can serve to reduce or prevent occurrences of electronic components 110,112 being separated from redistribution structure 114. In some examples, underfill 124 can extend up and/or contact the lateral sides of electronic components 110, 112. In some examples, underfill 124 can extend to backside 113 of electronic component 110 and the backside of electronic component 112. While underfill 124 is shown extending continuously between electronic component 110 and electronic component 112, in some examples, a portion of inner side 120 of redistribution structure 114 can be exposed in gap 210.

FIG. 2C shows electronic device 100 at a later stage of manufacture. In the example of FIG. 2C, encapsulant 126 can be provided. Encapsulant 126 can be disposed over redistribution structure 114, electronic component 110, and electronic component 112. Encapsulant 126 can fill gap 210 defined between electronic component 110 and electronic component 112. Encapsulant 126 can extend to inner side 120 of redistribution structure 114. In some examples, encapsulant 126 can be between inner side 120 of redistribution structure 114 and electronic components 110, 112. For example, encapsulant 126 can comprise a molded underfill (MUF) and can replace underfill 124.

In various examples, encapsulant 126 can comprise or be referred to as a body, a package body, or a molding. Encapsulant 126 can comprise an epoxy mold compound, a resin, a filler-reinforced polymer, a B-stage pressed film, or gel. Encapsulant 126 can be formed by transfer molding, compression molding, liquid encapsulant molding, vacuum lamination, paste printing, film assisted molding, or any other suitable process. Encapsulant 126 is a protective layer and can protect semiconductor devices from external environments. Encapsulant 126 can protect electronic components 110, 112 and redistribution structure 114 from external moisture, dust, and impact.

FIG. 2D shows electronic device 100 at a later stage of manufacture. In the example of FIG. 2D, encapsulant 126 is removed from an upper side of electronic device 100. Encapsulant 126 can be removed to expose electronic components 110 and 112. In some examples, encapsulant 126 can be substantially coplanar with backside 113 of electronic component 110 and the backside 213 of electronic component 112. As used herein to describe coplanarity, the term substantially coplanar can mean within manufacturing tolerances of coplanarity.

In some examples, a grinding, etching, ablation, chemical-mechanical planarization (CMP), or other removal process can be performed to remove the upper portion of encapsulant 126. In some examples, a portion of encapsulant 126 can be removed by backgrinding. Backgrinding can be performed by grinding the back side of electronic device 100 to a reference thickness using a large-particle grinding wheel, and then finely adjusting the thickness through a micro-particle grinding wheel. In some examples, CMP can be used to remove material from an outer side of encapsulant 126. Encapsulant 126 can be substantially removed from outer side 113 of electronic component 110 and from the backside 213 of electronic component 112. Backside 113 of electronic component 110 and backside 213 of electronic component 112 can be exposed from and substantially coplanar with an outer side 224 of encapsulant 126.

FIG. 2E shows electronic device 100 at a later stage of manufacture. In the example of FIG. 2E, metallic structure 128 can be provided. Metallic structure 128 can have an inner side 229 coupled to outer side 224 of encapsulant 126, to backside 113 of electronic component 110, and to backside 213 of electronic component 112. Inner side 229 of metallic structure 128 can be substantially flat against outer side 224 of encapsulant 126, against backside 113 of electronic component 110, and against backside 213 of electronic component 112. Metallic structure 128 can extend over encapsulant 126, over electronic component 110, over electronic component 112, and over redistribution structure 114. For example, metallic structure 128 can, in some examples, extend beyond the footprint of electronic component 110 and/or beyond the footprint of electronic component 112.

In some examples, the thickness of metallic structure 128 can be less than the thickness of redistribution structure 114. For example, metallic structure 128 can be approximately 5%, approximately 10%, approximately 15%, approximately 20%, or approximately 25% thinner than redistribution structure 114. In some examples, the thickness of metallic structure 128 can range from between 2 μm and 35 μm, between 5 μm and 25 μm, or between 10 μm and 15 μm.

In some examples, metallic structure 128 can be coupled directly to semiconductor material of electronic component 110 and electronic component 112. Metallic structure 128 can comprise metals, alloys, or other compounds. In some examples, metallic structure 128 can comprise a stacked structure. For example, a layer of titanium can be provided, a layer of aluminum can be provided over the titanium layer, and a copper layer can be provided over the aluminum layer. Other metals, alloys, and metallic compounds can be used as layers in various examples. In some examples, metallic structure 128 can comprise a thin adhesion layer (e.g., Ti or TiW) with a second material applied over it. In some examples, metallic structure 128 can include nonmetallic components. For example, material can be sputtered or plated over the adhesion layer. In some examples, SiC, SiN, AlN, AlSiC, steel, nickel, or other suitable materials having desired CTE properties, or stiffness properties, can be plated over the adhesion layer or over other layers. In some examples, metallic structure 128 can include copper formed over the adhesion layer and nickel can be formed over the copper layer to tune the CTE of metallic structure 128. In some examples, metallic structure 128 can include nickel with copper formed over the nickel layer. In some examples, the nickel layer can be thinner than the copper layer. For example, the nickel layer can be between 1 μm and 5 μm or between 2 μm and 3 μm, and the copper layer can be between 5 μm and 15 μm or between 8 μm and 12 μm. In some examples, the nickel layer can be approximately 2 μm and the copper layer can be approximately 10 μm. In some examples, copper can be formed (e.g., plated) directly on outer side 224 of encapsulant 126, backside 113 of electronic component 110, and/or backside 213 of electronic component 112

The material used for metallic structure 128 is selected based on CTE properties similar to those of redistribution structure 114. For example, the difference between the overall CTE of metallic structure 128 and the overall CTE of redistribution structure 114 can be less than the difference between the overall CTE of metallic structure 128 and the CTE of electronic component 110 and/or less than the difference between the overall CTE of metallic structure 128 and the CTE of electronic component 112. For example, the overall CTE of metallic structure 128 can be within approximately 5%, approximately 10%, approximately 15%, approximately 20%, or approximately 25% of the overall CTE of redistribution structure 114. Metallic structure 128 can also be selected partially based on thermal conductivity in electronic devices 100 and to provide benefit of heat dissipation. Some materials can be selected for metallic structure 128 based on stiffness.

In some examples, metallic structure 128 can be selectively formed to tune the CTE of metallic structure 128 to offset the CTE of redistribution structure 114 or otherwise tune the CTE of electronic device 100. Metallic structure 128 can comprise multiple layers of different materials selected to tune the CTE of metallic structure 128 and of electronic device 100. Metallic structure 128 can also be formed in various shapes or patterns over the upper side of electronic device 100, with some patterns being illustrated in the example figures. Shapes of metallic structure 128 are illustrated as rectangular in the examples in the figures, though metallic structure 128 could have triangular, polygonal, irregular, round, elliptical or other suitable geometries.

The shape, CTE, and location of metallic structure 128 on electronic device 100 can be selected to offset smile or frown characteristics of electronic device 100 in response to temperature changes. For example, using the CTE of metallic structure 128 to compensate for the difference between the CTE of redistribution structure 114 and the CTE of electronic components 110,112 can reduce cry shape warpage of redistribution structure 114 at room temperature.

In some examples, metallic structure 128 can be provided by electroless plating, electrolytic plating, sputtering, physical vapor deposition (PVD), chemical vapor deposition (CVD), metalorganic chemical vapor deposition (MOCVD), atomic layer deposition (ALD), liquid phase chemical vapor deposition (LPCVD), plasma enhanced chemical vapor deposition (PECVD), or any other suitable deposition. In some examples, a seed layer can be formed by electroless plating, electrolytic plating, sputtering, PVD, CVD, MOCVD, ALD, LPCVD, PECVD, or any other suitable deposition process, and can comprise one or more layers of titanium (Ti), titanium tungsten (TiW), tungsten (W), chromium (Cr), aluminum (Al), nickel (Ni), gold (Au), silver (Ag), or copper (Cu). A pattern can be provided over the seed layer in examples in which metallic structure 128 is selectively positioned. Metallic structure 128 can be provided over the seed layer by electroless plating, electrolytic plating, sputtering, PVD, CVD, MOCVD, ALD, LPCVD, PECVD, or any other suitable deposition.

In various examples, metallic structure 128 can be provided by masking a desired shape of metallic structure 128 and sputtering material over encapsulant 126, electronic component 110, and electronic component 112. In some examples, metallic structure 128 can be selectively plated and can comprise a CTE and thickness selected to balance warpage, while providing thermal heat dissipation. For example, the greater the CTE of redistribution structures 114, the greater the CTE and/or the thickness of metallic structure 128. In some examples, having thinner redistribution structures 114 (e.g., redistribution structures 114 having four or fewer RDL layers), metallic structure 128 can comprise a CTE of approximately 10, 15, 16, 17, 18, 19, or 20. In some examples, having thicker redistribution structures 114 (e.g., redistribution structures 114 having five or more RDL layers), metallic structure 128 can comprise a CTE of approximately 20, 21, 22, 23, 24, or 25. Alternatively, a lower CTE metallic structure 128 (e.g., CTE less than 20) can be used with a thicker redistribution structure 114 (e.g., five RDL layers or greater) by making metallic structure 128 thicker. The material and thickness of metallic structure 128 can be selected to balance the CTE of metallic structure 128 against the CTE of redistribution structure 114, which can reduce warpage of electronic device 100.

Referring now to FIG. 2F, electronic device 100 is shown at a later stage of manufacture. In the example of FIG. 2F, electronic device 100 can be released from carrier 200 (FIG. 2E), flipped, and coupled to carrier 230. Carrier 230 may be similar to or the same as carrier 200 described above. In some examples, metallic structure 128 can be coupled to carrier 230 by a temporary bond layer, as previously described above with reference to carrier 200.

In some examples, external interconnects 130 can be provided over outer terminals 118o. External interconnects 130 can be coupled to outward terminals 118o. In some examples, external interconnects 130 can comprise tin (Sn), silver (Ag), lead (Pb), copper (Cu), Sn—Pb, Sn₃₇—Pb, Sn₉₅—Pb, Sn—Pb—Ag, Sn—Pb—Bi, Sn—Cu, Sn—Ag, Sn—Au, Sn—Bi, Sn—Ag—Cu, Sn—Ag—Bi, Sn—Zn, or Sn—Zn—Bi. In some examples, after temporarily placing a conductive material containing solder on outward terminals 118o through a ball drop method, external interconnects 130 can be completed through a reflow process. External interconnects 130 can comprise or be referred to as conductive balls such as solder balls, conductive pillars such as copper pillars, conductive posts, bumps, or solder capped copper pillars. In some examples, external interconnects 130 can be referred to as external input/output terminals of electronic device 100. In some examples, electronic device 100 can be implemented in a land grid array (LGA) configuration and outer terminals 118o can serve as external input/output terminals and electronic device 100 can be devoid of external interconnects 130.

FIG. 2G shows electronic device 100 at a later stage of manufacture. In the example of FIG. 2G, electronic devices 100 can be diced or singulated from a larger workpiece into individual electronic devices 100. In accordance with various examples, singulation can be performed by cutting through saw streets, for example indicated by lines 135, disposed around a perimeter of electronic devices 100, thereby separating individual electronic devices 100 from one another. Singulation can be performed using, for example, mechanical cutting (e.g., sawing, cutting, polishing, or snapping), energy cutting (e.g., laser cutting, plasma cutting, etc.), or chemical cutting (e.g., etching or melting). Singulation can include cutting through encapsulant 126, redistribution structure 114, and, in some examples, metal structure 128. In some examples, after singulation, encapsulant 126 can be coplanar with the lateral sides of redistribution structure 114. In some examples, metal structure 128 can be coplanar with the lateral sides of encapsulant 126 and redistribution structure 114.

In accordance with various examples, electronic device 100 may define a beam-neutral axis A extending through semiconductor region 240. The CTEs of upper portion 242 and of lower portion 244 can be larger than the CTE through semiconductor region 240. In some examples, the CTE of upper portion 242 can be substantially balanced with the CTE of lower portion 244 to resist warpage in response to temperature changes. For example, the CTE of upper portion 242 can be within approximately 5%, approximately 10%, approximately 15%, approximately 20%, or approximately 25% of the CTE of lower portion 244. In some examples, metallic structure 128 can reduce cry shaped warpage of electronic device 100 during cooling (e.g., after reflow).

FIG. 2H shows a top view of electronic device 100 of FIG. 2G, with the location of electronic components 110 and 112 under metal structure 128 represented using dotted lines. With combined reference to FIG. 2G and FIG. 2H, metallic structure 128 can completely cover encapsulant 126, electronic component 110, and electronic component 112. Metallic structure 128 can cover an outer portion of encapsulant 126 located between the lateral side of electronic components 110,112 and the exterior sides of electronic device 100. Metallic structure 128 can cover a central portion 248 of encapsulant 126 disposed between electronic components 110 and 112.

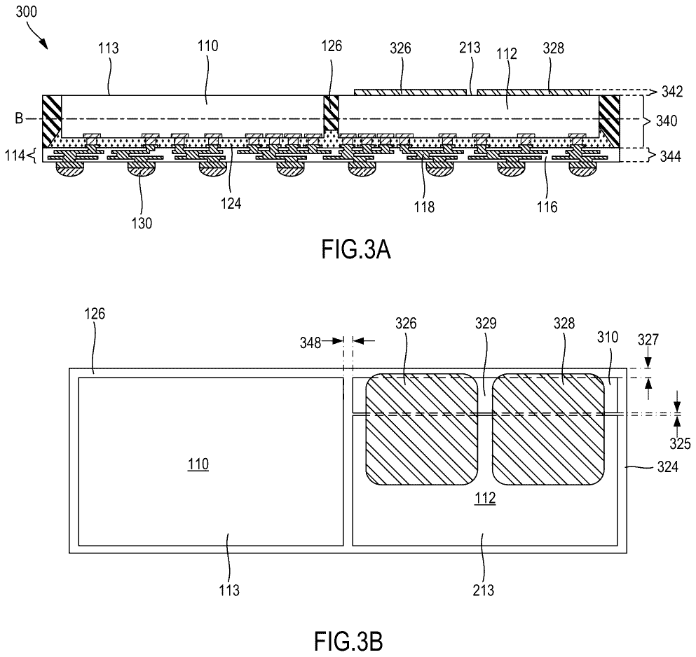

FIGS. 3A and 3B show an example electronic device 300 in cross-section and in top view, respectively. Metallic structure 326 and metallic structure 328 can be selectively provided (e.g., plated) over electronic component 112, encapsulant 126, and electronic component 310. Electronic component 110 and a central portion 348 of encapsulant 126 between electronic component 110 and electronic component 112 can be devoid of metallic structure 326 and metallic structure 328, in some examples. Metallic structures 326 and 328 can comprise strips that extend partially across electronic component 112, across electronic component 310, across portion 325 of encapsulant 126 between electronic component 112 and electronic component 310, and partially across a perimeter region 327 of encapsulant 324 between the lateral side of electronic component 310 and the exterior side of electronic device 300. Metallic structures 326 and 328 can be provided using techniques and materials similar to or the same as those described above for metallic structure 128. Electronic component 310 can be similar to or the same as electronic component 110 or electronic component 112, as previously described. In electronic device 300, the locations and characteristics (e.g., thickness, material, shape, CTE) of metallic structure 326 and metallic structure 328 can be selected or “tuned” based on the warpage tendencies of electronic device 300 at different temperatures. In this regard, some portions of electronic component 112 can be devoid of metallic structure 326 and metallic structure 328, while other portions of electronic component 112 can be covered by metallic structure 326 and metallic structure 328. Metallic structure 326 can have a different CTE than metallic structure 328, a different thickness, and/or be made of different materials, as compared to metallic structure 328.

Electronic device 300 can define a beam-neutral axis B extending through semiconductor region 340. The CTE of upper portion 342 and the CTE of lower portion 344 can be larger than the CTE through semiconductor region 340. The relative thicknesses of upper portion 342 and lower portion 344 can comprise different relative thicknesses such that the beam neutral axis does not evenly bisect the thickness of electronic device 300. In some examples, the CTE of upper portion 342 can be substantially balanced with the CTE of lower portion 344 to resist warpage in response to temperature changes. For example, the CTE of upper portion 342 can be within approximately 5%, approximately 10%, approximately 15%, approximately 20%, or approximately 25% of the CTE of lower portion 344. Selectively plated metallic structures 326 and 328 can improve thermal characteristics of electronic device 300 by providing improved heat dissipation for hot spots covered by metallic structure 326 or metallic structure 328.

In some examples, the CTE, thickness, and/or material(s) of metallic structure 326 can differ from the CTE, thickness, and/or material(s), respectively, of metallic structure 328. The characteristics of metallic structures 326 and 328 can be selected to offset warpage characteristics (e.g., frowning or smiling) of electronic device 300. In some examples, metallic structure 326 can be configured to offset frowning while metallic structure 328 can be configured to offset smiling, or metallic structure 326 can offset smiling while metallic structure 328 offsets frowning.

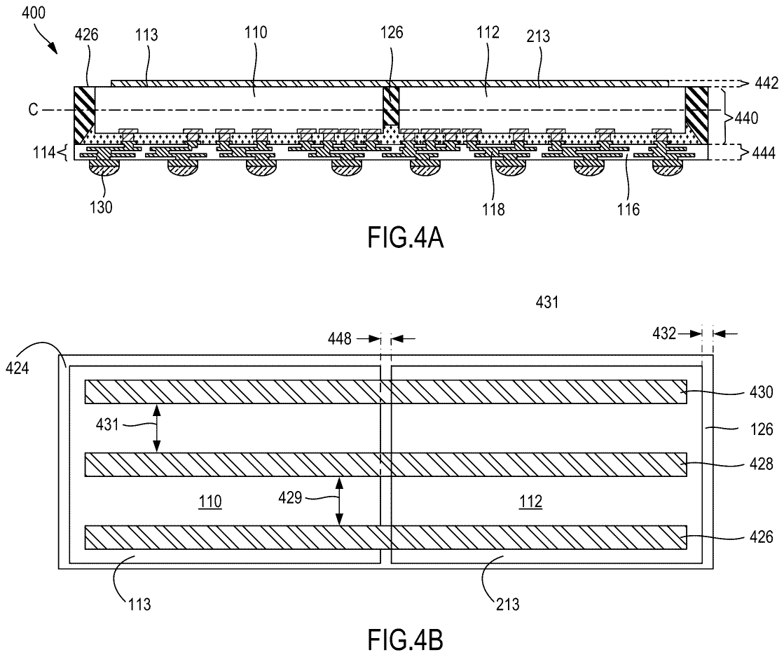

FIGS. 4A and 4B show an example electronic device 400 in cross-section and in top view, respectively. Metallic structures 426, 428, and 430 can be selectively provided (e.g., plated) over electronic component 112, encapsulant 126, and electronic component 110. Metallic structures 426, 428, and 430 can comprise strips that extend partially across electronic component 112, partially across electronic component 110, and across central portion 448 of encapsulant 126 between electronic component 112 and electronic component 110. An upper side 424 of encapsulant 126 can be exposed from metallic structures 426, 428, and 430 around a perimeter of electronic device 400. For example, an edge region 432 of upper side 424 of encapsulant 126 between the lateral sides of electronic components 110, 112 and the exterior side of electronic device 400 can be devoid of metallic structures 426, 428, and 430. Metallic structures 426, 428, and 430 can be provided using techniques and materials similar to or the same as those described above for metallic structure 128. In electronic device 400, the locations and characteristics (e.g., thickness, material, shape, CTE) of metallic structure 426, metallic structure 428, and metallic structure 430 can be selected or “tuned” based on the warpage tendencies of electronic device 400 at different temperatures. In this regard, some portions of backside 113 of electronic component 110 and backside 213 of electronic component 112 can be devoid of metallic structures 426, 428, and 430 while other portions of backsides 113 and 213 can be covered. Metallic structure 426 can have a different CTE than metallic structure 428 and/or than metallic structure 430. Metallic structure 426 can have also a different thickness and/or be made of different materials, as compared to metallic structure 428 and/or metallic structure 430.

Electronic device 400 may define a beam-neutral axis C extending through semiconductor region 440. The CTE of upper portion 442 and the CTE of lower portion 444 of electronic device 400 can be larger than the CTE through semiconductor region 440. In some examples, the CTE of upper portion 442 can be substantially balanced with the CTE of lower portion 444 to resist warpage in response to temperature changes. For example, the CTE of upper portion 442 can be within approximately 5%, approximately 10%, approximately 15%, approximately 20%, or approximately 25% of the CTE of lower portion 444. In addition to warpage prevention, selectively plated metallic structures 426, 428, and 430 can improve thermal characteristics of electronic device 400 by providing improved heat dissipation for hot spots covered by metallic structures 426, 428, and 430.

FIG. 4B shows a top view of electronic device 400 of FIG. 4A. Metallic structures 426, 428, and 430 can cover portions of upper side 424 of encapsulant 126, electronic component 112, and electronic component 110. Gap 431 can be defined between metallic structure 430 and metallic structure 428. Gap 429 can be defined between metallic structure 428 and metallic structure 426. Metallic structures 426, 428, and 430 may partially cover central portion 448 of encapsulant 424 between electronic component 110 and electronic component 112.

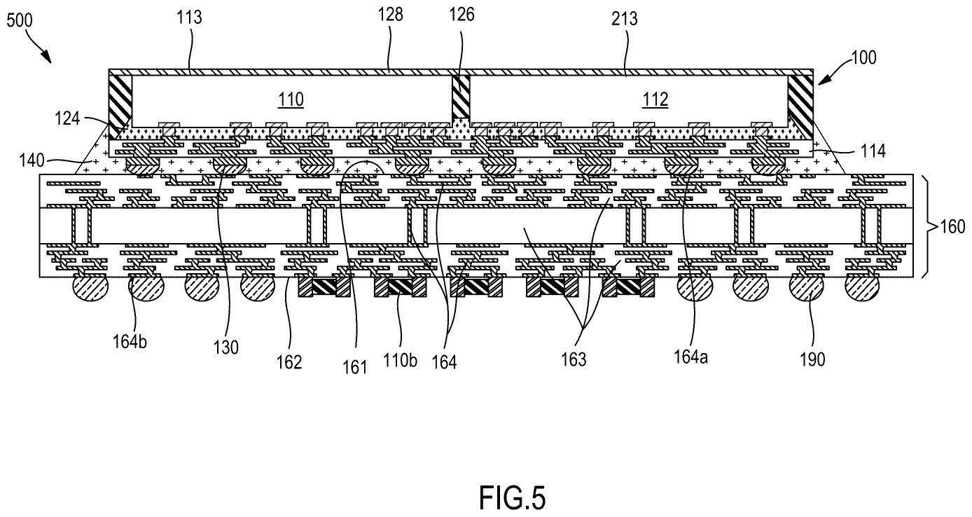

Referring now to FIG. 5, electronic device 500 is shown, in accordance with various examples. In the example of FIG. 5, electronic device 500 comprises an electronic module such as, for example, electronic device 100, coupled to inner side 161 of substrate 160. Electronic device 100 is used only as a non-limiting example, and it is contemplated that other embodiments could include different modules with a metallic structure 128 tuned to reduce bowing or warpage of an electronic module in response to temperature changes.

In accordance with various examples, heating during reflow of external interconnects 190, or cooling after reflow, can result in warpage (e.g., bowing into a frowning or smiling shape) of electronic device 100. Continuing the example, electronic device 500 including electronic device 100, having metallic structure 128 tuned to resist warpage of electronic device 100 during heating or cooling, can lead to reduced warpage of electronic device 100, such that warpage or bowing is within reasonable tolerances. Reduced warpage of electronic device 100 can improve electrical connections between substrate 160 and electronic device 100 (e.g., between external interconnects 130 of electronic device 100 and inner terminals 164a of conductive structure 164 of substrate 160.

An underfill material 140 can be disposed between substrate 160 and electronic device 100. Substrate 160 can include dielectric structure 163 and conductive structure 164. Substrate 160 can be a preformed substrate or RDL substrate, as previously described. Passive devices 110b can be coupled to outer side 162 of substrate 160. External device interconnects 190 can be coupled to outer terminals 164b of conductive structure 164 of substrate 160.

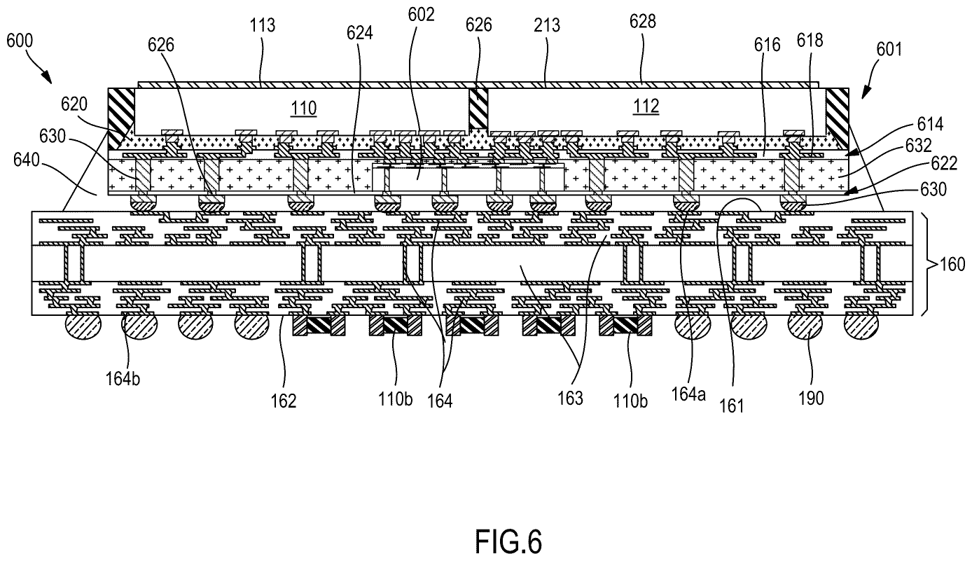

With reference to FIG. 6, electronic device 600 is shown, in accordance with various embodiments. Electronic device 600 can be similar to electronic device 500 (of FIG. 5) but can include an electronic module (also referred to as an electronic device) 601 coupled to inner side 161 of substrate 160. Electronic device 601 can include electronic component 110 (as previously described), electronic component 112 (as previously described), bridge die 602, redistribution structure 614, redistribution structure 620, vertical interconnects 630, encapsulant 626, underfill 619, metallic structure 628, encapsulant 632, and external interconnects 630. Bridge die 602 can electrically couple electronic component 110 to electronic component 112. In some examples, metallic structure 628 can include multiple strips extending partially over electronic components 110 and 112, similar to metallic structures 426, 428, 430 of electronic device 400. In some examples, metallic structure 628 can be similar to metallic structure 128 and can completely cover electronic components 110 and 112 and/or encapsulant 626. It will be appreciated that these are used only as non-limiting examples, and it is contemplated that metallic structure 628 can have any desired shape(s) and/or thickness(es), and/or combination(s) of materials, configured/tuned to reduce bowing or warpage of an electronic module 601 in response to temperature changes.

The example of FIG. 6, bridge die 602 and vertical interconnects 630 can be surrounded by encapsulant 632. Encapsulant 632 can comprise or be referred to as a body, a package body, or a molding. Encapsulant 126 can comprise an epoxy mold compound, a resin, a filler-reinforced polymer, a B-stage pressed film, or gel. Encapsulant 632 can be provided using techniques and materials similar to or the same as those described above for encapsulant 126. Redistribution structure 614 can be provided over encapsulant 632. Redistribution structure 614 can include dielectric structure 616 and conductive structure 618. The elements, features, materials, or manufacturing methods of redistribution structure 614 can be similar to or the same as those described above for redistribution structure 114. Conductive structure 618 can be electrically coupled to vertical interconnects 630 and bridge die 602. Electronic component 110 and electronic component 112 can be provided over redistribution structure 614. Conductive structure 618 can electronically couple electronic component 110 and electronic component 112 to vertical interconnects 630 and bridge 602. Electronic component 110 can electrically communicate with electronic component 112 via bridge die 602. Underfill 620 can be provided between electronic components 110, 112 and redistribution structure 614, similar to underfill 124 in electronic device 100. Encapsulant 626 can be provided around electronic components 110, 112 and over redistribution structure 614, similar to encapsulant 126 in electronic device 100.

A redistribution structure 622 can be provided on the side of encapsulant 632 opposite redistribution structure 614. Redistribution structure 622 can include dielectric structure 624 and conductive structure 626. The elements, features, materials, or manufacturing methods of redistribution structure 622 can be similar to or the same as those described above for redistribution structure 114. Vertical interconnects 630 can be coupled between conductive structure 618 of redistribution structure 614 and conductive structure 626 of redistribution structure 622. In some examples, bridge die 602 can also be electrically coupled between conductive structure 618 of redistribution structure 614 and conductive structure 626 of redistribution structure 622. For example, bridge die 602 can include through silicon vias (TSVs), in some examples. External interconnects 630 can be coupled to conductive structure 626 of redistribution structure 622. External interconnects 630 can couple module 601 to substrate 160.

Metallic structure 628 can be formed (e.g., plated) on backside 113 of electronic component 110, backside 213 of electronic component 112 and/or outer side 627 of encapsulant 626. Metallic structure 628 can tuned to offset warpage or bowing of electronic device 601 in response to temperature changes. Tuning can take into consideration warpage characteristics and/or tendencies of redistribution structure 114, bridge die 602, electronic component 110, and/or electronic component 112. In some examples, a lower portion of electronic device 601 including redistribution structure 614, bridge die 602, encapsulant 632, vertical interconnects 630, and redistribution structure 622 can have a CTE between approximately 7 and approximately 30 or between approximately 10 and approximately 20. An upper portion of electronic device 601 including metallic structure 628 can have a CTE that is substantially balanced with the CTE of the lower portion to resist warpage of electronic device 601 in response to temperature changes. For example, the CTE of the upper portion of electronic device 601 can be within approximately 5%, approximately 10%, approximately 15%, approximately 20%, or approximately 25% of the CTE of the lower portion of electronic device 601.

Electronic devices and related methods can improve mechanical behavior of electronic devices during temperature changes. The CTE of a redistribution structure, electronic components, and encapsulant can be analyzed to identify locations of the electronic device and materials for selectively providing a metallic structure to reduce warpage. The metallic structure can be added above a beam-neutral axis of the electronic device with the redistribution structure located below the beam-neutral axis. The selective placement of the metallic structure can result in a CTE on an upper side of an electronic component that matches or approximates the CTE of a redistribution structure or other structure on a lower side of the electronic component. Metallic structures can be tuned to limit warpage or bowing in electronic devices.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a redistribution structure comprising a first coefficient of thermal expansion (CTE);
a first electronic component disposed over the redistribution structure;
a second electronic component disposed adjacent the first electronic component and over the redistribution structure, wherein a gap is defined between the first electronic component and the second electronic component;
a first encapsulant around the first electronic component and the second electronic component, wherein a backside of the first electronic component and a backside of the second electronic component are substantially coplanar with an outer side of the first encapsulant; and
a metallic structure disposed directly on the outer side of the first encapsulant, the backside of the first electronic component, and the backside of the second electronic component, wherein the metallic structure comprises a second CTE.

2. The electronic device of claim 1, wherein the metallic structure covers the outer side of the first encapsulant, the backside of the first electronic component, and the backside of the second electronic component.

3. The electronic device of claim 1, wherein the metallic structure comprises a strip that extends partially across the first electronic component, across a gap between the first electronic component and the second electronic component, and partially across the second electronic component.

4. The electronic device of claim 1, wherein the metallic structure extends partially across the first electronic component.

5. The electronic device of claim 1, wherein the first CTE of the redistribution structure is between approximately 17 parts per million change per degree Celsius (ppm/° C.) and approximately 30 ppm/° C., and wherein the second CTE of the metallic structure is between approximately 17 ppm/° C. and approximately 20 ppm/° C.

6. The electronic device of claim 1, wherein the second CTE of the metallic structure is within 20% of the first CTE of the redistribution structure.

7. The electronic device of claim 1, further comprising:
a bridge die coupled to a side of the redistribution structure opposite the first electronic component;
a second encapsulant surrounding the bridge die; and
a plurality of vertical interconnects in the encapsulant;
wherein a lower portion of the electronic device comprises the redistribution structure, the bridge die, the second encapsulant, and the vertical interconnect structures,
wherein a CTE of the lower portion of the electronic device is between 7 parts per million change per degree Celsius (ppm/° C.) and 20 ppm/° C., and
wherein the second CTE of the metallic structure is within between 5% and 25% of the CTE of the lower portion of the electronic device.

8. The electronic device of claim 1, wherein the metallic structure comprises a first conductive layer and a second conductive layer over the first conductive layer.

9. The electronic device of claim 1, wherein the metallic structure comprises copper, aluminum, or aluminum silicon carbide.

10. An electronic device, comprising:
a redistribution structure;
a first electronic component disposed over the redistribution structure;
a second electronic component disposed adjacent the first electronic component and over the redistribution structure;
an encapsulant disposed around lateral sides of the first electronic component and the second electronic component; and
a metallic structure disposed over the encapsulant and the first electronic component, wherein a first coefficient of thermal expansion (CTE) above a beam-neutral axis of the electronic device is balanced with a second CTE below the beam-neutral axis of the electronic device.

11. The electronic device of claim 10, wherein the metallic structure comprises a plurality of strips partially covering the first electronic component and the second electronic component.

12. The electronic device of claim 10, wherein the metallic structure covers the first electronic component and the second electronic component.

13. The electronic device of claim 10, wherein the metallic structure comprises strips that extend partially across the first electronic component, across a first portion of the encapsulant, across the second electronic component, and partially across a second portion of the encapsulant.

14. The electronic device of claim 10, wherein the redistribution structure comprises a CTE of between approximately 17 parts per million change per degree Celsius (ppm/° C.) and 30 ppm/° C., wherein the metallic structure comprises a CTE of approximately 17 ppm/° C.

15. The electronic device of claim 10, wherein the metallic structure further comprises a first conductive layer and a second conductive layer over the first conductive layer.

16. A method of manufacturing an electronic device, comprising:
providing a redistribution structure;
providing a first electronic component over the redistribution structure;
providing a second electronic component adjacent the first electronic component and over the redistribution structure;
providing an encapsulant disposed around lateral sides of the first electronic component and the second electronic component; and
providing a metallic structure over the encapsulant and the first electronic component, wherein a coefficient of thermal expansion (CTE) of the metallic structure is within 25% of a CTE of the redistribution structure.

17. The method of claim 16, further comprising:
forming a first portion of the metallic structure having a first CTE and a first thickness; and
forming a second portion of the metallic structure have a second CTE and a second thickness.

18. The method of claim 17, wherein the first CTE is different from the second CTE.

19. The method of claim 17, wherein the first thickness is different from the second thickness.

20. The method of claim 16, wherein providing the metallic structure over the encapsulant comprises plating the material of the metallic structure directly on the encapsulant, the first electronic component, and the second electronic component.
